(19) United States
(12) Patent Application Publication
(10) Pub. No.: US 2019/0144990 A1
(43) Pub. Date: May 16, 2019

(54) Device For Sputtering A Material Onto A Surface Of A Substrate While Moving

(71) Applicant: Oliver James Groves, Freeland, WA (US)

(72) Inventor: Oliver James Groves, Freeland, WA (US)

(21) Appl. No.: 15/815,675

(22) Filed: Nov. 16, 2017

(51) Int. Cl. C23C 14/35; H01J 37/34; C23C 14/34; C23C 14/08; C23C 14/06

(52) U.S. Cl. CPC C23C 14/35; H01J 37/3414; C23C 14/0605; C23C 14/087; C23C 14/34

(57) ABSTRACT

The present invention provides a device for sputtering a material onto a substrate having a surface. The device comprises a chamber that has a target window where sputtering of the surface of the substrate takes place, via a force produced by a pair of magnets. The magnets are moved across the surface of the substrate via a motor of the device. Furthermore, a method of using such a device for sputtering is also contemplated.

### TECHNICAL FIELD

The present invention relates to a device for sputtering a material onto a surface of a substrate.

### BACKGROUND OF THE INVENTION

The subject invention generally relates to a device for sputtering a material onto a surface of a substrate, and particularly, such a device that allows for mobile sputtering across a surface of a substrate that is larger than the point at which sputtering takes place.

### BRIEF SUMMARY OF EMBODIMENTS OF THE INVENTION

According to one embodiment of the invention, a device for sputtering a material onto a substrate having a surface comprises a chamber. The chamber comprises a target window where sputtering of the surface of the substrate takes place, via a force produced by a pair of magnets. The magnets are moved across the surface of the substrate via a motor of the device.

Furthermore, a method of using such a device for sputtering is also contemplated.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1 is a first perspective illustrative side view of a preferred embodiment of the device of the invention;

FIG. 2 is a second perspective illustrative side view of the preferred embodiment of the device of the invention;

FIG. 3 is a perspective illustrative top view of the preferred embodiment of the device of the invention;

FIG. 4 is a third perspective illustrative side view of the preferred embodiment of the device of the invention;

FIG. 5 is a first perspective illustrative view of a section of the preferred embodiment of the device of the invention;

FIG. 6 is a second perspective illustrative view of a section of the preferred embodiment of the device of the invention;

FIG. 7 is a perspective illustrative zoomed-in view of a section of the preferred embodiment of the device of the invention;

FIG. 8 is a perspective illustrative view of another section of the preferred embodiment of the device of the invention;

FIG. 9 is a perspective illustrative view of a further section of the preferred embodiment of the device of the invention; and

FIG. 10 is a perspective illustrative bottom view of the preferred embodiment of the device of the invention.

FIGS. 11A and 11B are a flow chart of a method of sputtering a material onto a surface of a substrate, while moving.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

From time-to-time, the present invention is described herein in terms of example environments. Description in terms of these environments is provided to allow the various features and embodiments of the invention to be portrayed in the context of an exemplary application. After reading this description, it will become apparent to one of ordinary skill in the art how the invention can be implemented in different and alternative environments.

Unless defined otherwise, all technical and scientific terms used herein have the same meaning as is commonly understood by one of ordinary skill in the art to which this invention belongs. All patents, applications, published applications and other publications referred to herein are incorporated by reference in their entirety. If a definition set forth in this section is contrary to or otherwise inconsistent with a definition set forth in applications, published applications and other publications that are herein incorporated by reference, the definition set forth in this document prevails over the definition that is incorporated herein by reference.

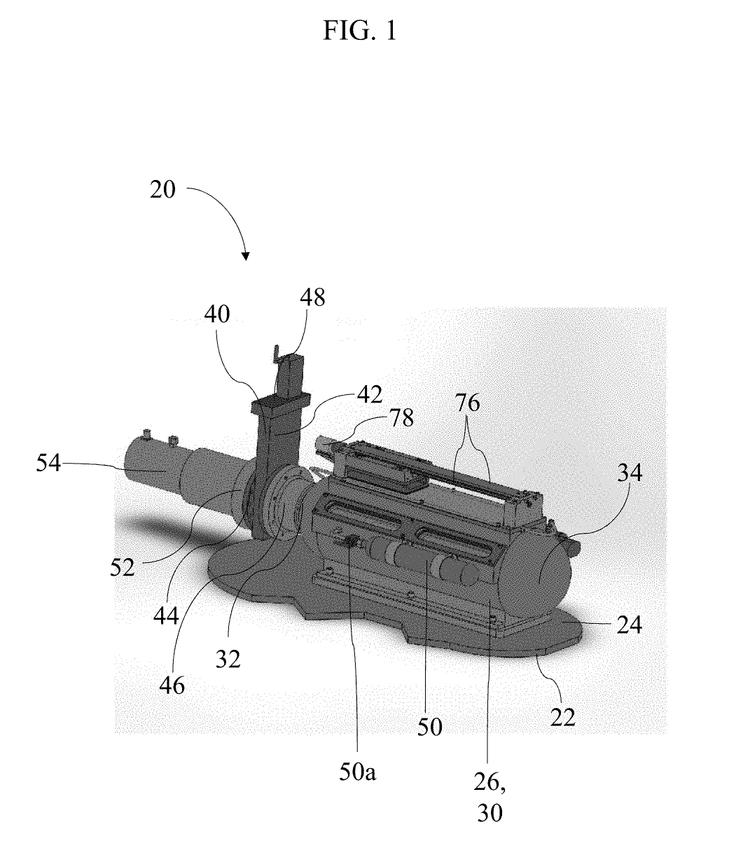

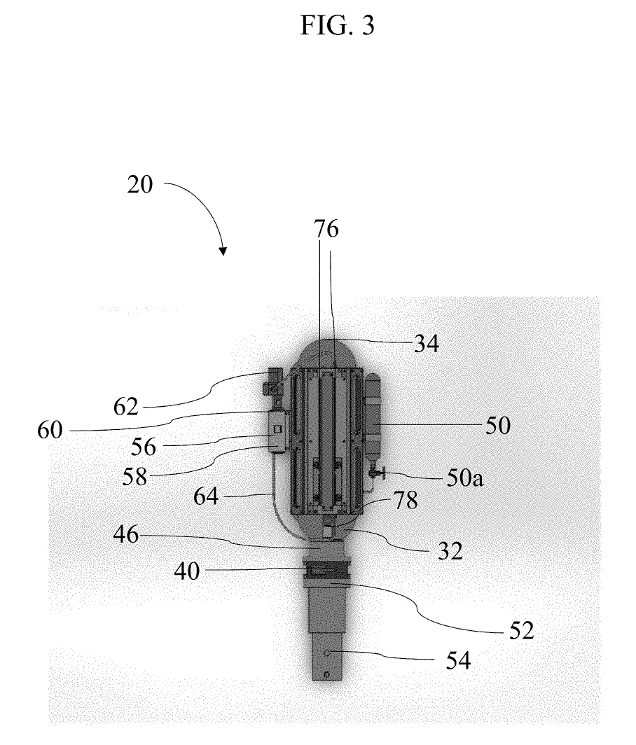

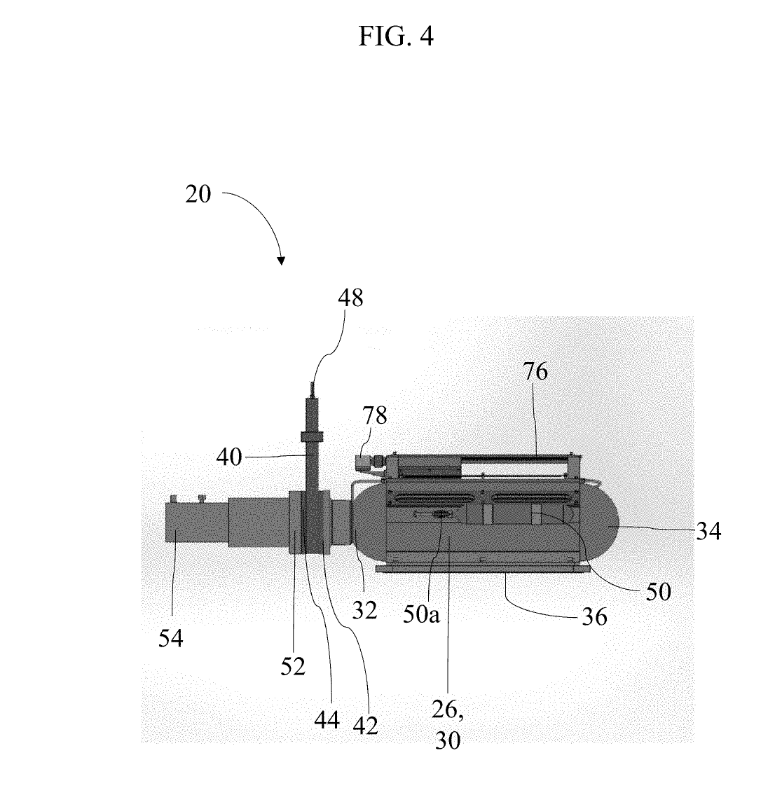

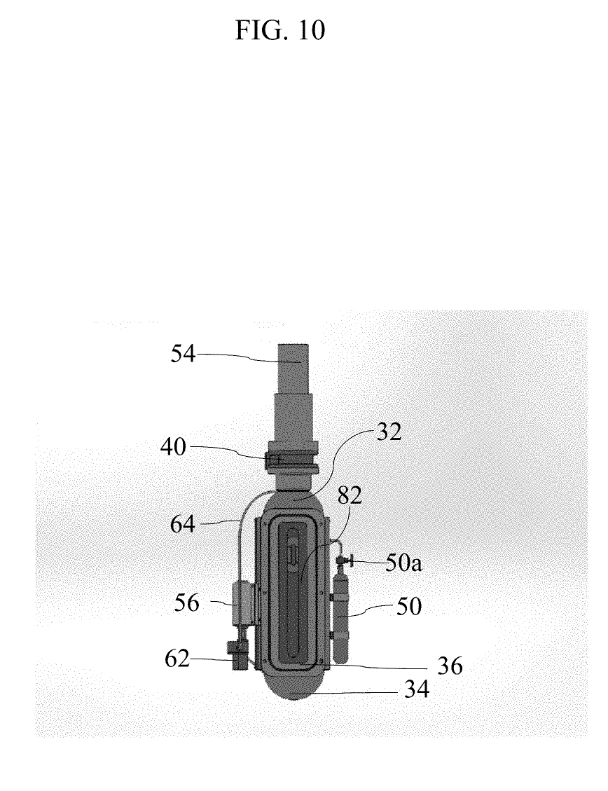

Referring first to FIG.1, the present invention provides a device 20 for sputtering a material (for instance, copper or carbon composite) onto a substrate 22 having a surface 24. The device 20 comprises a chamber 26, which in turn comprises an interior space 28, an exterior 30, a first end 32 and a second end 34. The interior space 28 of the chamber 26 comprises a plurality of walls. The exterior 30 of the chamber 26 comprises a bottom side 36, best depicted in FIG. 10. The bottom side 36 of the exterior 30 of the chamber 26 comprises a target window 38 where sputtering of the surface 24 of the substrate 22 takes place. As best indicated in FIG. 4, the first end 32 of the chamber 26 connects to a first flange 46, which in turn connects to a valve 40 having a first side 42 and a second side 44 and a top end 48. The top end 48 of the valve 40 connects to a first pump (not pictured) for removing atmosphere from the interior space 28 of the chamber 26. The first pump creates a vacuum of at least 80 millibars within the interior space 28 of the chamber 26. First indicated in FIG. 1 and again in FIG. 3, the exterior 30 of the chamber 26 comprises a bottle 50 housing a noble gas (preferably helium). The noble gas enters into the interior space 28 of the chamber 26. The bottle 50 comprises a needle 50a for regulating entry of the noble gas into the interior space 28 of the chamber 26. The second side 44 of the valve 40 attaches to a second flange 52 for connecting to a second pump 54. The second pump 54 compresses and cryogenically vapor-freezes the noble gas to be introduced into the interior space 28 of the chamber 26.

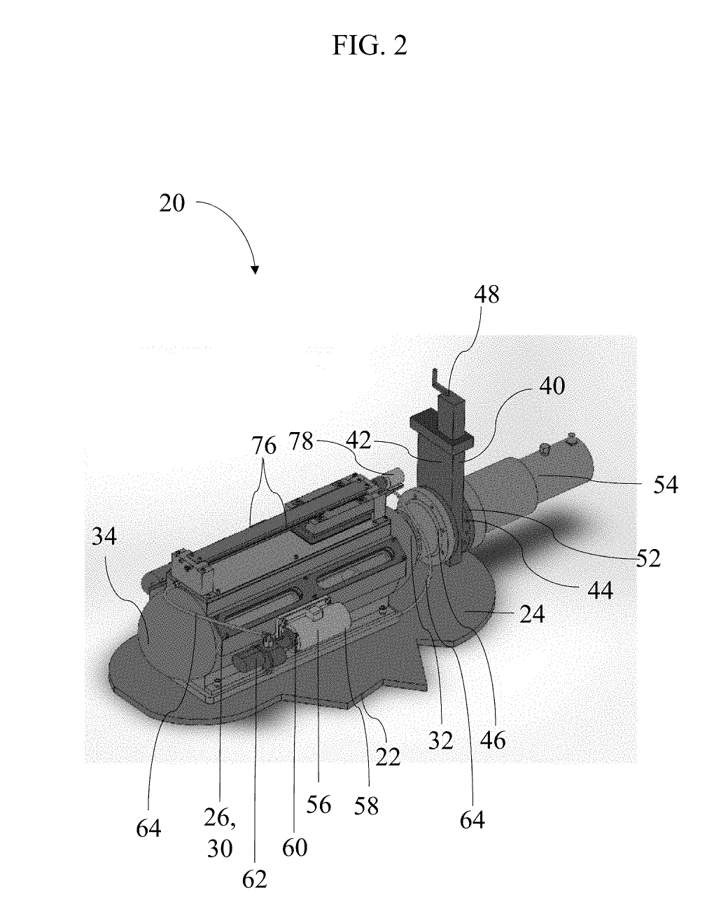

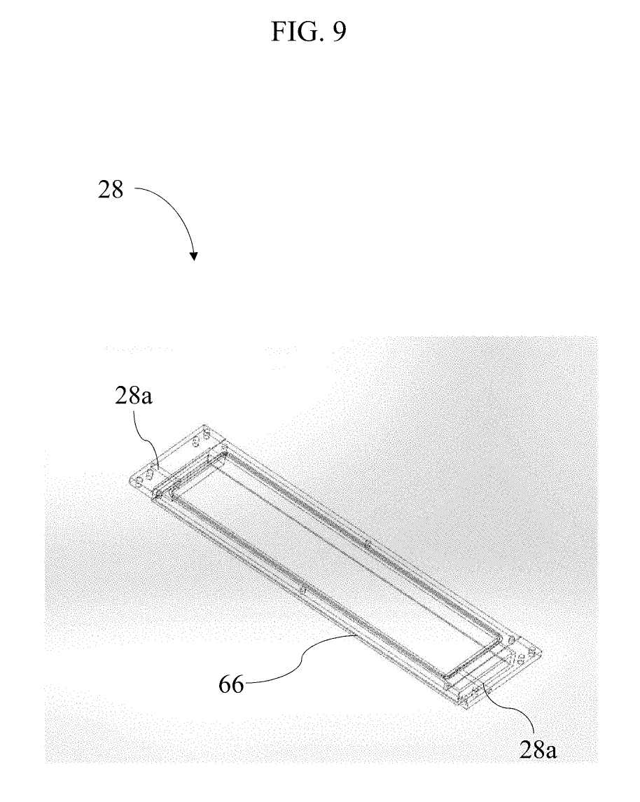

A first assembly circulates a stream of water throughout a path 28a (FIG. 9) within the interior space 28 of the chamber 26. The first assembly comprises a third pump 56, first depicted in FIG. 2, powered by electricity via a first motor 62, for providing a force to move the stream of water. The third pump 56 has a first end 58 and a second end 60. The first assembly further comprises at least one hose 64 connected to the first end 58 of the third pump 56, providing a route for flow of the stream of water throughout the path 28a within the interior space 28 of the chamber 26, and rejoining at the second end 60 of the third pump 56. The at least one hose 64 comprises a tube for inlet pressure for water flowing into the path 28a, and a tube for outlet pressure for water flowing out of the path 28a.

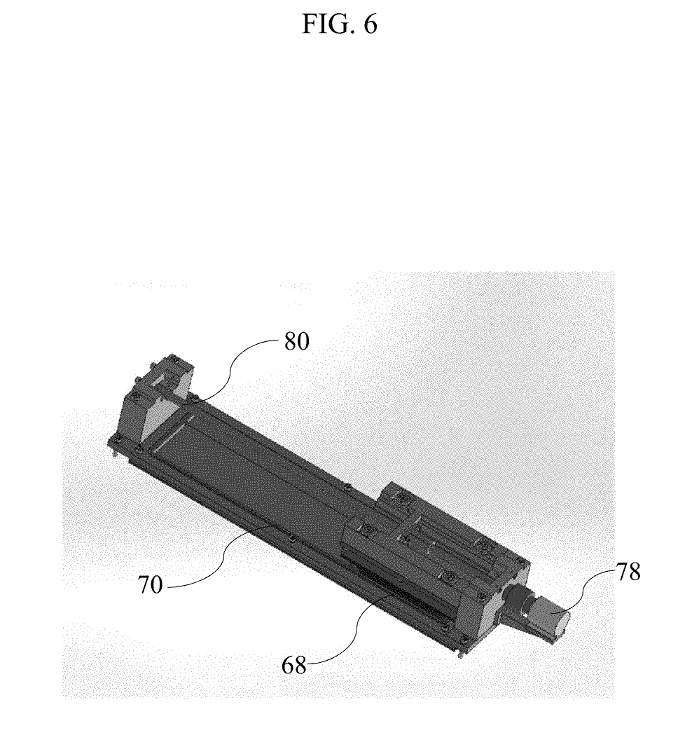

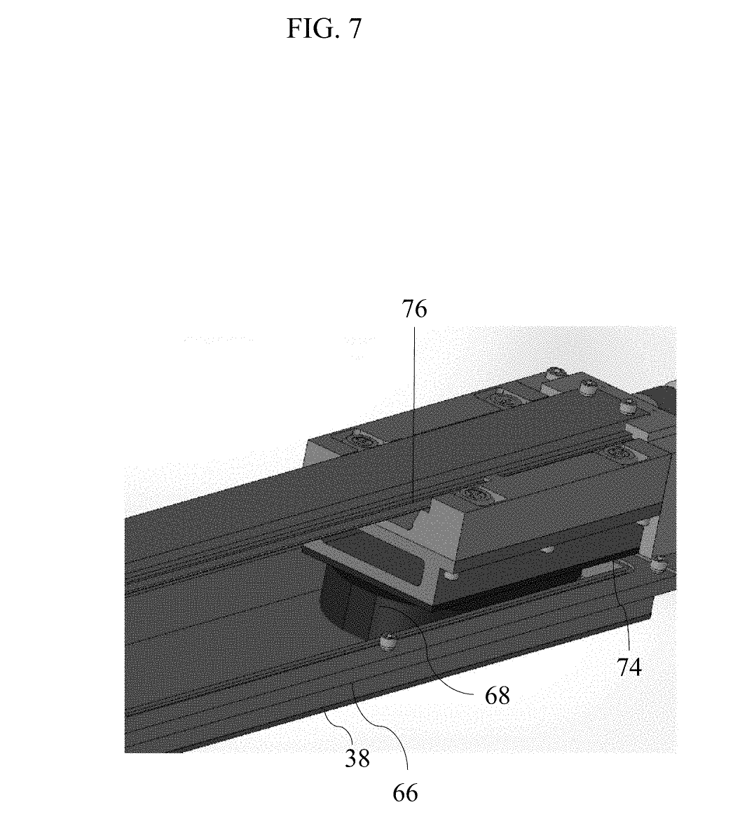

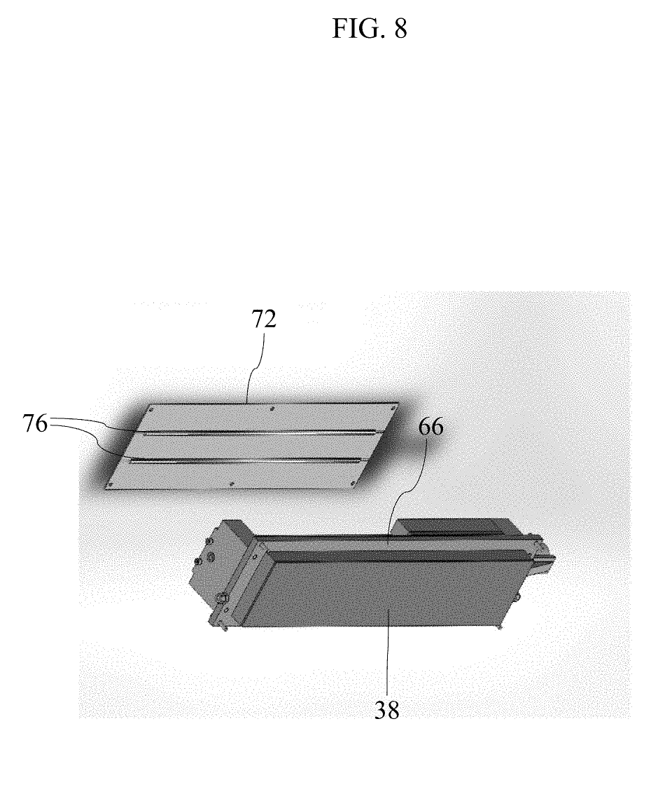

A second assembly (FIG. 6) is located at the top side of the exterior 30 of the chamber 26. The second assembly comprises a housing 66 for a cathode. The housing 66 for the cathode provides a positively-charged field to the target window 38 of the bottom side 36 of the exterior 30 of the chamber 26. The cathode comprises a first magnet 68 (FIG. 7) within a pool of water. The housing 66 for the cathode has a top edge over which is placed an O-ring 70, over which is placed a cover 72 (FIG. 8). As further depicted in FIG. 7, the second assembly further comprises a carriage. The carriage of the second assembly comprises a second magnet 74 for generating a force along with the first magnet 68, and a pair of opposing parallel rails 76 for attaching the second assembly to the first end 32 of the chamber 26 and the second end 34 of the chamber 26.

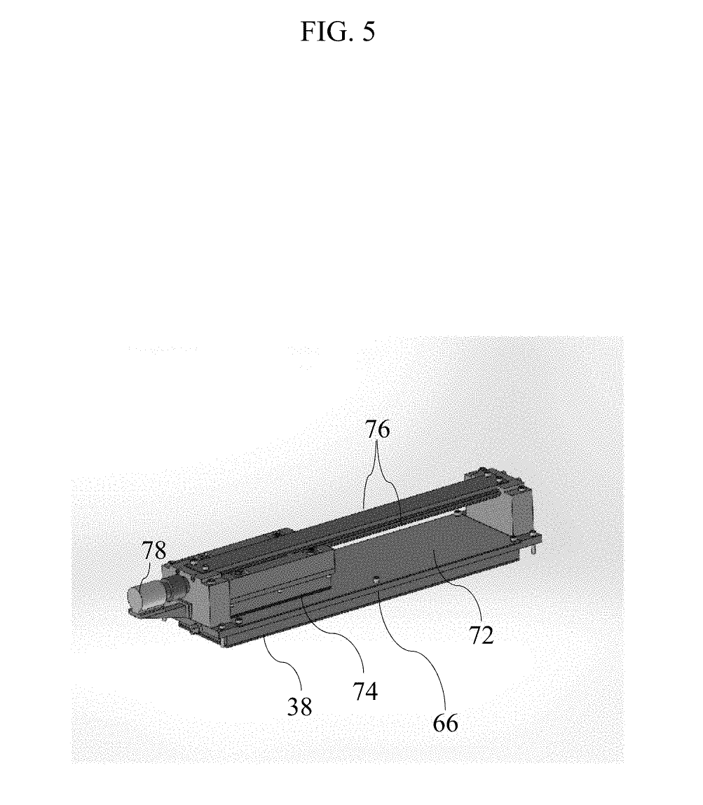

A third assembly, first illustrated in FIG. 5, is attached to the first end 32 and the second end 34 of the chamber 26, opposite the bottom side 36 of the exterior 30 of the chamber 26. The third assembly comprises a second motor 78 for providing electricity to the carriage of the second assembly. The second motor 78 of the third assembly is located at the first end 32 of the chamber 26, and placed on a shaft spool 80 extending from the first end 32 of the chamber 26 to the second end 34 of the chamber 26. The second motor 78 of the third assembly runs continuously while turning from one direction to another. The bottom side 36 of the exterior 30 of the chamber 26 comprises a template 82 for removably-contacting the surface 24 of the substrate 22. The template 82 comprises an anode for providing a negatively-charged field and reducing sputtering on a damaged area of the surface 24 of the substrate 22.

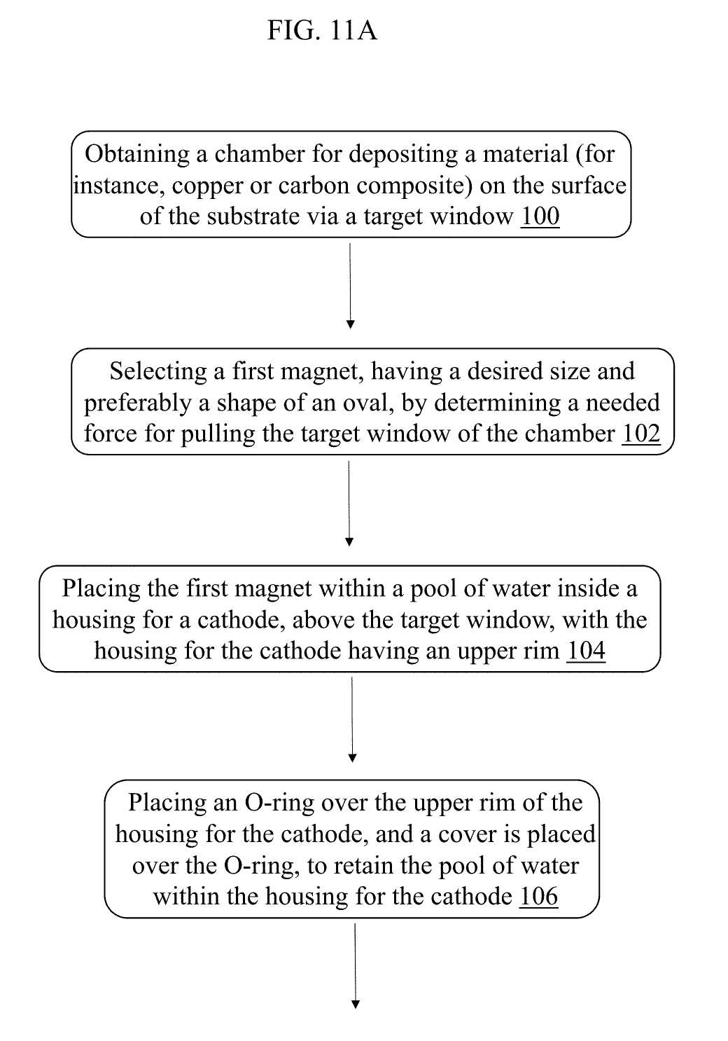

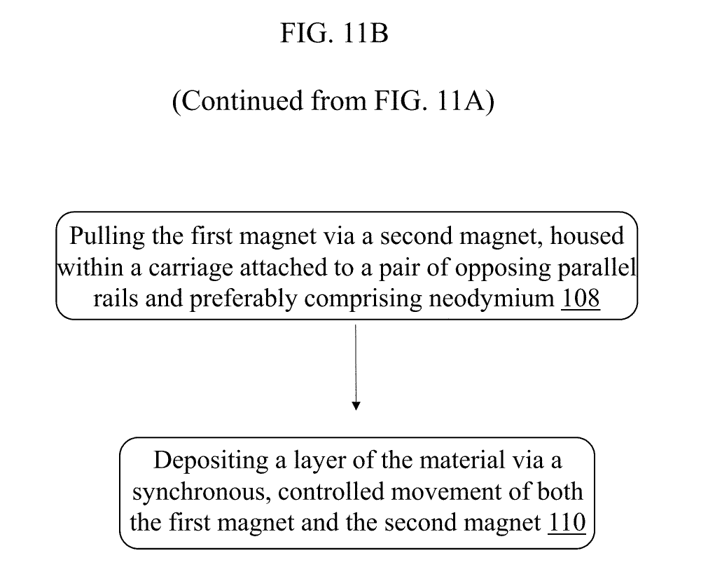

Referring to FIGS. 11A and 11B, a method for continuous sputtering across a surface of a substrate comprises the following steps: a chamber is obtained for depositing a material (for instance, copper or carbon composite) on the surface of the substrate via a target window 100. A first magnet is selected, having a desired size and preferably a shape of an oval, by determining a needed force for pulling the target window of the chamber 102. The first magnet is placed within a pool of water inside a housing for a cathode, above the target window, with the housing for the cathode having an upper rim 104. An O-ring is placed over the upper rim of the housing for the cathode, and a cover is placed over the O-ring, to retain the pool of water within the housing for the cathode 106. The first magnet is pulled via a second magnet, housed within a carriage attached to a pair of opposing parallel rails and preferably comprising neodymium 108. A layer of the material is deposited via a synchronous, controlled movement of both the first magnet and the second magnet 110.

What is claimed is:

1. A device for sputtering a material onto a substrate having a surface, comprising:
a chamber comprising an interior space, an exterior, a first end and a second end;
the interior space of the chamber comprising a plurality of walls;
the exterior of the chamber comprising a bottom side;
the bottom side of the exterior of the chamber comprising a target window where sputtering of the surface of the substrate takes place;
the bottom side of the exterior of the chamber comprising a template for removably contacting the surface of the substrate; and
the template comprising an anode for providing a negatively-charged field and reducing sputtering on a damaged area of the surface of the substrate.

2. The device of claim 1, wherein the material is copper.

3. (canceled)

4. The device of claim 1, wherein the first end of the chamber comprising a valve having a first side and a second side;
the first side of the valve of the chamber connecting to a first flange, in turn connected to a first pump for removing atmosphere from the interior space of the chamber;
the exterior of the chamber comprising a bottle housing a noble gas;
the noble gas entering into the interior space of the chamber;
the bottle comprising a needle for regulating entry of the noble gas into the interior of the chamber;
the second side of the valve attached to a second flange for connecting to a second pump;
the second pump compressing and cryogenically vapor-freezing the noble gas to be introduced into the interior space of the chamber;

5. The device of claim 1, wherein the first pump creates a vacuum of at least 80 mbars within the interior space of the chamber.

6. The device of claim 1, wherein the noble gas is helium.

7. The device of claim 4, further comprising:
a first assembly for circulating a stream of water throughout the plurality of walls of the interior space of the chamber;
the first assembly comprising a third pump, powered by electricity via a first motor, for providing a force to move the stream of water;
the third pump having a first end and a second end; and the first assembly further comprising at least one hose connected to the first end of the third pump, providing a route for flow of the stream of water, and rejoining at the second end of the third pump.

8. The device of claim 7, further comprising:
a second assembly, located at the top side of the exterior of the chamber;
the second assembly comprising a housing for a cathode;
the housing for the cathode providing a positively-charged field to the target window of the bottom side of the exterior of the chamber;
the cathode comprising a first magnet within a pool of water;
the housing for the cathode having a top edge over which is place an O-ring, over which is placed a cover;
the second assembly further comprising a carriage;
the carriage of the second assembly comprising a second magnet for generating a force along with the first magnet, and a pair of opposing parallel rails for attaching the second assembly to the first end of the chamber and the second end of the chamber;
a third assembly attached to the first end and the second end of the chamber;
the third assembly comprising a second motor for providing electricity to the carriage of the second assembly;
the second motor of the third assembly located at the first end of the chamber, and placed on a shaft spool extending from the first end of the chamber to the second end of the chamber; and
the second motor of the third assembly running continuously while turning from one direction to another.

9. The device of claim 8, wherein the first magnet has a shape of an oval.

10. The device of claim 8, wherein the second magnet is comprised of neodymium.

11. (canceled)

12. A method for continuous sputtering across a surface of a substrate, comprising the steps of:
providing a chamber coating a target for depositing a material from the target onto the surface of the substrate via a of the chamber;
introducing charged plasma in the chamber;
providing a first magnet above the target, the first magnet being configured to confine the charged plasma in a vicinity of the target below the target;
placing the first magnet within housing having a pool of water and covering the housing with a cover, with a cover the cover comprising two first rails extending into the housing and configured to limit the motion of the first magnet along a desired direction;
moving the first magnet inside the housing by moving the second magnet on a carriage attached to a second rail; and
depositing a layer of the material via a synchronous, controlled movement of both the first magnet and the second magnet.

13. The method of claim 12, further comprising placing an O-ring over a upper rim of the housing, wherein the cover is placed over the O-ring, to retain the pool of water within the housing.

14. The method of claim 12, wherein the material is copper or a carbon composite.

15. (canceled)

16. The method of claim 12, wherein the first magnet has a shape of an oval.

17. The method of claim 12, wherein the second magnet comprises neodymium.

18. The method of claim 12, wherein the cover is negatively charged and forms a cathode configured for pulling positive ions of the plasma to hit the target, thereby releasing the material from the target so that the material travels to the substrate via the window

19. The method of claim 13, wherein the first rails are electrically non-conductive.

20. The method of claim 12, wherein the first magnet is replaceable by at least another magnet having a different magnetic force.

21. A method for continuous sputtering across a surface of a substrate, comprising the steps of:
providing a chamber containing a target for depositing a material from the target onto the surface of the substrate via a window of the chamber;
introducing charged plasma into the chamber via a nozzle movable along a first shaft located inside the chamber;
providing a first magnet above the target, the first magnet being configured to confine the charged plasma in a vicinity of the target below the target;
placing the first magnet within housing having a pool of water and covering the housing;
providing a cathode configured for pulling positive ions of the plasma to hit the target, thereby releasing the material from the target so that the material travels to the substrate via the window;
providing a second magnet located above the first magnet and outside the housing;
moving the first magnet inside the housing by moving the second magnet on a carriage attached to a second rail;
moving the nozzle to be under the first magnet during use via a synchronous, controlled movement of the first magnet, the second magnet, and the nozzle, such that the nozzle, thereby injecting the plasma under the first magnet during use.

22. The method of claim 21, wherein:
the nozzle has an inlet joined to flexible tubing leading from a container of a noble gas used for production of the charged plasma and an outlet for delivering the noble gas into the chamber;
the nozzle is joined to a spool shaft via a Thomson lead nut, the spool shaft being configured to be rotated around a central axis of the spool shaft and the Thomson lead nut being configured to convert a rotation of the spool shaft into a translation motion along the central axis of the spool shaft;
the spool shaft is parallel to the first shaft;
an outer surface of the first shaft is magnetized negatively;
the nozzle is joined to the first shaft via at least one magnetic bearing, each magnetic bearing comprising a loop traversed by the first shaft and having an inner surface magnetized negatively and an outer surface magnetized positively, such that the inner surface of each bearing is repelled by the outer surface of the first shaft; and
each bearing has an inner diameter larger than a diameter of the first shaft, such that the each bearing loosely fits around the first shaft, allowing the bearing to travel along the first shaft without touching the first shaft.
